(19) United States
(12) Patent Application Publication
(10) Pub. No.: US 2006/0194355 A1
(43) Pub. Date: Aug. 31, 2006

(54) Laser diode bar provided with a parallel connected diode for bridging said laser siode bar in case of failure

(76) Inventors: Franz Eberhard, Regensburg (DE); Gerhard Herrmann, Bernhardswald (DE); Josip Maric, Sinzing (DE); Michael Schwind, Sinzing (DE); Martin Behringer, Regensburg (DE); Alexander Behres, Kelheim (DE)

Correspondence Address: COHEN, PONTANI, LIEBERMAN & PAVANE, 551 FIFTH AVENUE, SUITE 1210, NEW YORK, NY, 10176, US

(21) Appl. No.: 10/540,902

(22) PCT Filed: Nov. 6, 2003
(86) PCT No.: PCT/DE03/03683

§ 371 Date: Mar. 18, 2006

(30) Foreign Application Priority Data
Dec. 27, 2002 (DE) 102613095
Feb. 14, 2003 (DE) 103063129

(51) Int. Cl. H01L 21/00

(52) U.S. Cl. 438/22

(57) ABSTRACT

A laser diode component comprising a laser diode bar on which a specific operating voltage is impressed during operation and with which a bridging element is connected in parallel, which bridging element is in a current-blocking state when the specific operating voltage is impressed on the associated laser diode bar and which bridging element changes over to a current-conducting state as soon as the voltage drop across the laser diode bar exceeds the operating voltage by a predefined voltage value. A circuit arrangement comprising a plurality of such laser diode components which are connected in series is furthermore specified.

The invention relates to a laser diode component according to the preamble of patent claim 1 and an electronic circuit arrangement in accordance with the preamble of patent claim 11. It relates in particular to a laser diode component and to a circuit arrangement comprising one or a plurality of high-power laser diode bars.

Failure of a laser diode bar may give rise to the interruption of the current flow via the laser diode bar. In a circuit arrangement comprising a plurality of laser diode bars or laser diode bar modules connected in series with one another this leads to the complete failure of all the laser diode bars or modules of the affected series. In order to eliminate the failure, it has been customary hitherto to exchange the entire series with the failed laser diode bar.

The present invention is based on the object of providing a laser diode bar and a circuit arrangement in which failure of an individual laser diode bar or module does not give rise to the complete failure of the entire series of laser diode bars or modules.

This object is achieved by means of a laser diode bar having the features of patent claim 1 and by means of a circuit arrangement having the features of patent claim 11.

Preferred embodiments and advantageous developments of the invention are specified in the dependent claims 2 to 10 and 12 to 20.

The arrangement according to the invention provides for connecting a bridging element, in particular in the form of a semiconductor component, in parallel with a diode laser such that, in the event of failure of the diode laser resulting in an interruption or a severe reduction of the current flow via said laser, the bridging element switches through and electrically bridges the failed diode laser. Instead of the semiconductor component, it is also possible to use a mechanical element, for example a relay. The bridging element has to be configured in such a way that it is at sufficiently high impedance during proper operation of the diode laser and that it switches through in the case of a defective high-impedance diode laser on account of the increased voltage drop and electrically bridges the diode laser, so that the remaining diode lasers in a series circuit still remain supplied with current.

The bridging element may have a single suitable electrical element (for example diode, etc. (see further below)) or a plurality of electrical elements connected in parallel or in series. It is equally possible to use a plurality of bridging elements connected in series or in parallel.

A preferred switching element is a diode, in particular an AlGaAs diode, whose diffusion voltage (also called threshold voltage) is higher than the operating voltage of the diode laser. The diffusion voltage is preferably at least 200 mV higher than the operating voltage of the diode laser. This advantageously ensures, on the one hand, a reliable operation of a properly functioning diode laser even in the event of voltage fluctuations and, on the other hand, a reliable switching to the on state in the event of a failure of the associated diode laser.

In a preferred refinement of a laser diode component according to the invention, the diode laser and the associated bridging element are applied on a common heat sink, the bridging element is fixed on the heat sink by means of a first connecting means and the diode laser is fixed on the heat sink by means of a second connecting means. The melting point of the first connecting means is at a higher temperature than that of the second connecting means. This advantageously avoids the situation in which, when the bridging element is mounted on to the heat sink before the diode laser is mounted, the connection between the bridging element and heat sink is damaged during the mounting of the diode laser. As an alternative, the diode laser and the bridging element can be mounted on the heat sink simultaneously or successively (preferably by means of heating the component itself) using the same connecting means or using similar connecting means.

Preferably, the bridging element is fixed on the heat sink by means of a hard solder and the laser diode bar by means of a soft solder.

The heat sink is, for example, a metallic cooling body or a metal carrier provided with a microchannel cooler structure, through which a cooling liquid is pumped. However, diode laser and bridging elements may also be mounted on to a common thermally conductive leadframe, which ensures a sufficient dissipation of heat from the diode laser.

In addition to the application of the arrangement according to the invention in the case of laser diode bars, the principle on which the invention is based can also be used in other devices and circuit arrangements in which a plurality of electronic components are connected in series and a bridging of a defective electronic component would lead to a total failure of the entire device or the entire circuit arrangement or a substantial part of the circuit arrangement. Therefore, it is expressly pointed out that such devices and circuit arrangements are also associated with the invention.

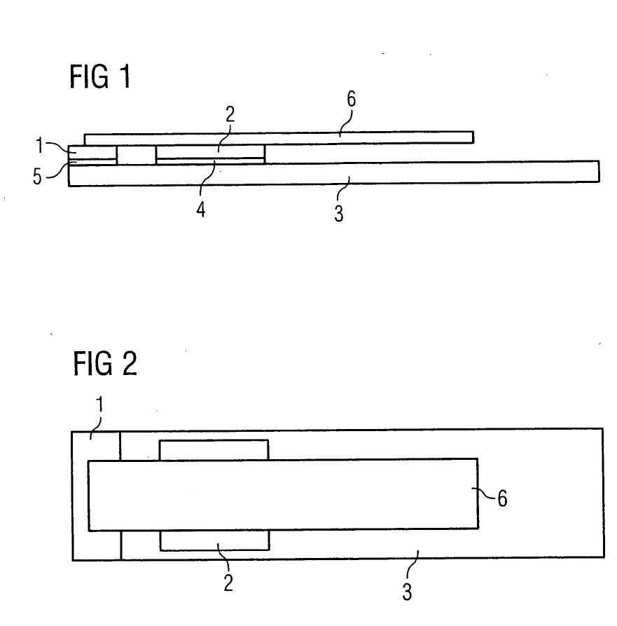

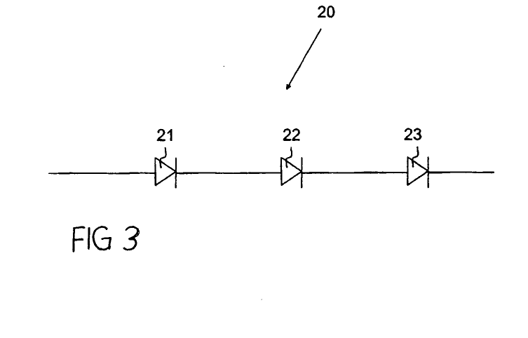

Further advantageous refinements and developments of the laser diode component according to the invention and of the circuit arrangement according to the invention emerge from the exemplary embodiment explained below in conjunction with FIGS. 1 and 2, in which:

FIG. 1 shows a sectional view through the exemplary embodiment, and

FIG. 2 shows a plan view of the exemplary embodiment.

In the exemplary embodiment, a laser diode bar 1 is mounted together with an AlGaAs diode 2 on a common metallic carrier 3. The laser diode bar 1 is fixed on the carrier 3 by means of a soft solder 4 (for example, indium solder) and the AlGaAs diode 2 is fixed on the carrier 3 by means of a hard solder 5 (for example, AuSn solder). The carrier 3 is a heat sink and in each case constitutes a first electrical connection of the laser diode bar 1 and of the AlGaAs diode 2.

The AlGaAs diode 2 is designed in such a way that its diffusion voltage is approximately 200 mV greater than the operating voltage of the laser diode bar 1.

A connection strip 6 spans the laser diode bar 1 and the AlGaAs diode 2 and is electrically conductively connected thereto by means of a metallic solder. The connection strip 6 in each case constitutes a second electrical connection of the laser diode bar 1 and of the AlGaAs diode 2.

In a process for producing such a laser diode component, firstly the AlGaAs diode 2 is fixed on the carrier 3 by means of the hard solder 5. Afterward, the metallic carrier 3 has indium vapor-deposited on it and is thereby prepared for the mounting of the laser diode bar 1. The laser diode bar 1 is subsequently applied by means of soft soldering on the carrier 3. Since the indium soldering is effected at a significantly lower temperature than the hard soldering of the AlGaAs diode 2, there is no risk of the connection between carrier 3 and AlGaAs diode 2 softening again during the mounting of the laser diode bar 1.

If, in the case of the arrangement described above, the laser diode bar 1 fails and it consequently no longer permits a current flow, the voltage between cathode (carrier) and anode (connection strip) rises greatly until the parallel diode 2 switches to the on state and essentially short-circuits the laser diode bar 1.

A laser diode component in accordance with the exemplary embodiment has the particular advantage that it is small and integrable.

In the case of a circuit arrangement according to the invention comprising laser diode components in accordance with the exemplary embodiment, a plurality of such laser diode components and thus a plurality of laser diode bars are connected in series with one another.

Instead of the AlGaAs diode 2, it is possible to use a suitable zener diode with regard to the switching voltage, a correspondingly suitable triac (breakover), a plurality of Si diodes connected in series or a mechanical switch/a mechanical fuse (for example a surge arrester, a spring on a solder ball or a bimetallic switch).

An arrangement using FET technology, SipMOS technology or CoolMOS technology can likewise be employed. A particular advantage of this technology is that an intelligent circuit arrangement with a low power loss can be realized and that the state of the associated laser diode can also be identified by remote interrogation. As an alternative, the use of a thyristor, a bipolar transistor, a relay or a manual switch as bridging element is also conceivable.

The scope of protection of the invention is not limited to the examples given herein above. The invention is embodied in each novel characteristic and each combination of characteristics, which particularly includes every combination of any features which are stated in the claims, even if this feature or this combination of features is not explicitly stated in the claims or in the examples.

This patent application claims the priority of German patent applications 102 61 309.5 of Dec. 27, 2002 and 103 06 312.9 of Feb. 14, 2003, the disclosure content of which is hereby explicitly incorporated by reference.

1. A laser diode component comprising a laser diode bar on which a specific operating voltage is impressed during operation, comprising:
a bridging element connected in parallel with the laser diode bar, which bridging element, when the specific operating voltage is impressed on the associated laser diode bar, transmits a smaller current than the laser diode bar or transmits no current and which bridging element switches over to such a low-impedance state that the laser diode bar is bridged as soon as the voltage drop across the laser diode bar exceeds the specific operating voltage by a predefined voltage value.

2. The laser diode component as claimed in claim 1, wherein
the bridging element changes over to the state that bridges the laser diode bar as soon as the voltage impressed on the bridging element is at least 200 mV higher than the specific operating voltage of the associated laser diode bar.

3. The laser diode component as claimed in claim 1, wherein
the bridging element has at least one diode which is forward-biased when the specific operating voltage is impressed on the associated laser diode bar and the diffusion voltage of which is at least 200 mV higher than the operating voltage of the associated laser diode bar.

4. The laser diode component as claimed in claim 2, wherein
the bridging element has a diode based on AlGaAs semiconductor material.

5. The laser diode component as claimed in claim 2, wherein
the bridging element has a series circuit comprising a plurality of diodes.

6. The laser diode component as claimed in claim 5, wherein
the series circuit has three Si diodes.

7. The laser diode component as claimed in claim 2, wherein
the bridging element has at least one zener diode, the breakdown voltage of which is at least 200 mV higher than the operating voltage of the associated laser diode bar.

8. The laser diode component as claimed in claim 2, wherein
the bridging element is a triac, the switching voltage of which is at least 200 mV higher than the operating voltage of the associated laser diode bar.

9. The laser diode component as claimed in claim 1, wherein
each laser diode bar and the associated bridging element are applied on a common heat sink, the bridging element is fixed on the heat sink by means of a first connecting means and the laser diode bar is fixed on the heat sink by means of a second connecting means, and the melting point of the first connecting means is at a higher temperature than that of the second connecting means.

10. The laser diode component as claimed in claim 9, wherein
the first connecting means is a hard solder and the second connecting means is a soft solder.

11. A circuit arrangement comprising a plurality of laser diode bars which are connected in series with one another and on which a specific operating voltage is in each case impressed during operation of the series circuit, comprising
a bridging element is connected in parallel with each laser diode bar, which bridging element, when the specific operating voltage is impressed on the associated laser diode bar, transmits a smaller current than the laser diode bar or transmits no current and which bridging element switches over to such a low-impedance state that the laser diode bar is bridged as soon as the voltage drop across the laser diode bar exceeds the specific operating voltage by a predefined voltage value.

12. The circuit arrangement as claimed in claim 11, wherein
the bridging element changes over to the state that bridges the laser diode bar as soon as the voltage impressed on the bridging element is at least 200 mV higher than the specific operating voltage of the associated laser diode bar.

13. The circuit arrangement as claimed in claim 11, wherein
the bridging element has at least one diode which is forward-biased when the specific operating voltage is impressed on the associated laser diode bar and the diffusion voltage of which is at least 200 mV higher than the operating voltage of the associated laser diode bar.

14. The circuit arrangement as claimed in claim 12, wherein
the bridging element has a diode based on AlGaAs semiconductor material.

15. The circuit arrangement as claimed in claim 12, wherein
the bridging element has a series circuit comprising a plurality of diodes.

16. The circuit arrangement as claimed in claim 15, wherein
the series circuit has three Si diodes.

17. The circuit arrangement as claimed in claim 12, wherein
the bridging element has at least one zener diode, the breakdown voltage of which is at least 200 mV higher than the operating voltage of the associated laser diode bar.

18. The circuit arrangement as claimed in claim 12, wherein
the bridging element is a triac, the switching voltage of which is at least 200 mV higher than the operating voltage of the associated laser diode bar.

19. The laser diode component as claimed in claim 11, wherein
each laser diode bar and the associated bridging element are applied on a common heat sink, in that the bridging element is fixed on the heat sink by means of a first connecting means and the laser diode bar is fixed on the heat sink by means of a second connecting means, and in that the melting point of the first connecting means is at a higher temperature than that of the second connecting means.

20. The circuit arrangement as claimed in claim 19, wherein
the first connecting means is a hard solder and the second connecting means is a soft solder.
